(19) United States
(12) Patent Application Publication
(10) Pub. No.: US 2026/0362621 A1
(43) Pub. Date: Nov. 12, 2026

(54) CIRCUIT BOARD SPACER

(71) Applicant: Enatel, Christchurch (NZ)

(72) Inventors: Chuan Cheong Yew, Christchurch (NZ); Tee Chek Tan, Christchurch (NZ); Joseph Cooper, Lyttelton (NZ)

(21) Appl. No.: 19/139,707

(22) PCT Filed: Dec. 15, 2022
(86) PCT No.: PCT/NZ2022/050171

§ 371 Date: Jun. 16, 2025

(51) Int. Cl. H05K 7/14; H05K 1/14

(52) U.S. Cl. CPC H05K 7/142; H05K 1/144; H05K 2201/2036

(57) ABSTRACT

A circuit board spacer for holding a first circuit board and a second circuit board in a fixed spatial relationship includes a first clamping portion configured to clamp to the first circuit board in response to rotation of the first clamping portion with respect to the first circuit board, a second clamping portion configured to clamp to the second circuit board, and a body portion, extending from the first clamping portion to the second clamping portion.

### BACKGROUND

The instant disclosure relates to spacers for holding two or more circuit boards in a fixed spatial relationship in a stack. Known circuit board spacers may include a threaded screw and nut assembly which requires screwing the screw while it is extended through an aperture in the circuit board. Other known circuit board spacers may include a simple cylinder or hollow cylinder that are not affixed to the circuit board.

### BRIEF DESCRIPTION OF THE DRAWINGS

FIG. 1 is a perspective view of an example circuit board spacer.

FIG. 2 is an exploded view of the example circuit board spacer of FIG. 1.

FIG. 3 is a perspective view of a first clamping portion of the example circuit board spacer of FIG. 1.

FIG. 4 is a side view of the first clamping portion of FIG. 3.

FIGS. 5 and 6 are perspective views of a body portion of the example circuit board spacer of FIG. 1.

FIG. 7 is a perspective view of a second clamping portion of the example circuit board spacer of FIG. 1.

FIG. 8 is a bottom view of the second clamping portion of FIG. 7.

FIG. 9 is a side view of the second clamping portion of FIG. 7.

FIG. 10 is a perspective view of an example circuit board spacer.

FIGS. 11 and 12 are side views of the example circuit board spacer of FIG. 10.

FIG. 13 is an exploded view of an example circuit board spacer.

FIG. 14 is a perspective view of an example circuit board spacer.

FIG. 15 is a side view of the example circuit board spacer of FIG. 14.

FIG. 16 is a top view of the example circuit board spacer of FIG. 14.

FIG. 17 is an exploded view of the example circuit board spacer of FIG. 14.

FIG. 18 is a side view of the example circuit board spacer of FIG. 10, with two circuit boards clamped in the example circuit board spacer.

FIG. 19 is a perspective view of an example circuit board assembly that includes two circuit boards and three example circuit board spacers.

FIG. 20 is a top view of the circuit board assembly of FIG. 18.

FIG. 21 is a bottom view of the circuit board assembly of FIG. 18.

FIG. 22 is a flow chart illustrating an example method of assembling a circuit board assembly using a circuit board spacer according to the present disclosure.

### DETAILED DESCRIPTION

Known circuit board spacers generally do not provide sufficient simplicity or ease of assembly. For example, some known spacers apply undue stress to the circuit board when two portions of the spacer are joined (e.g., because a screw is turned while in an aperture of the circuit board), which can damage traces and connections on the board or dislodge components on the board. In another example, some known spacers do not sufficiently affix to the board and may permit movement of the board if the assembly moves. Furthermore, known spacers do not provide sufficient adaptability or modularity in that a particular spacer can generally only be used to create a single spacing height between two circuit boards.

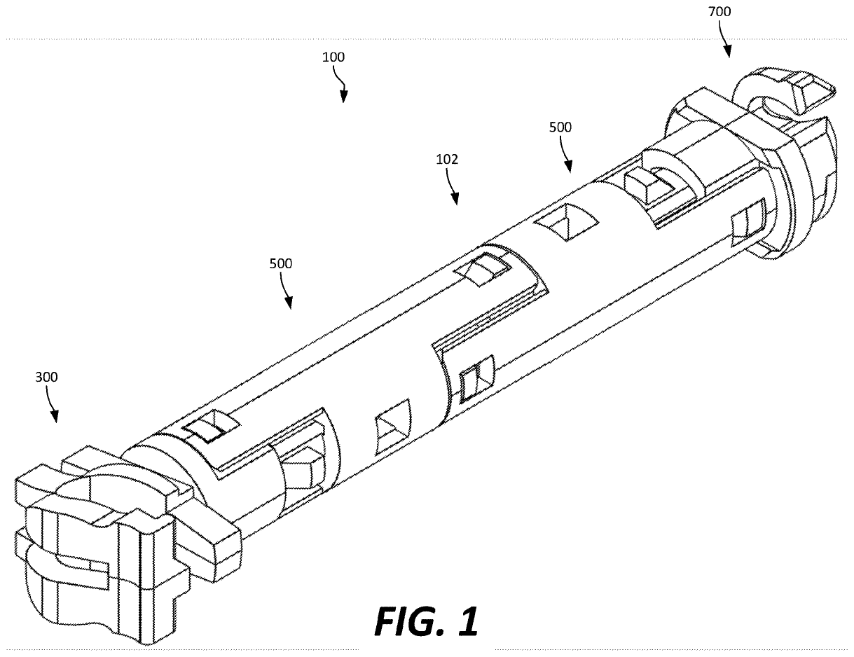

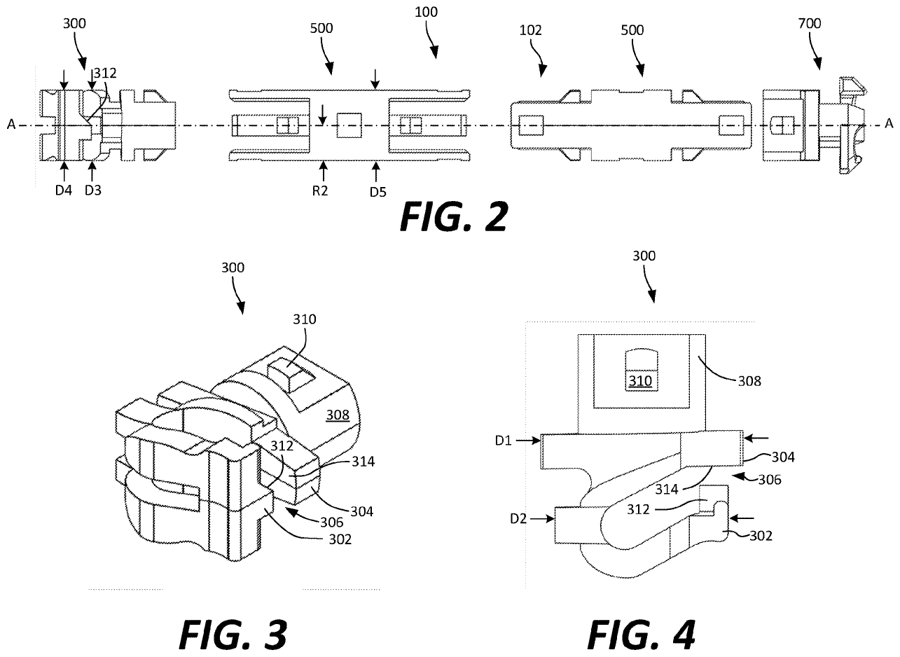

Referring to the figures, wherein like numerals refer to the same or similar features in the various views, FIGS. 1 and 2 are perspective and exploded views, respectively, of an example circuit board spacer (which may be referred to herein simply as a “spacer”) 100. The spacer 100 may include a first clamping portion 300, a second clamping portion 700, and a body portion 102 extending from the first clamping portion 300 to the second clamping portion 700. The spacer 100 may be used in conjunction with two circuit boards to form a circuit board assembly, with the first clamping portion 300 clamped or otherwise coupled to a first circuit board, and the second clamping portion 700 clamped or otherwise coupled to a second circuit board.

In some embodiments, the spacer 100 may include a multi-piece assembly. The first clamping portion 300 may be a separate, physically detachable component from the second clamping portion 700, and both the first and second clamping portions 300, 700 may be separate, physically detachable components from the body portion 102. Further, the body portion 102 may comprise two or more pieces, such as two or more identical body components 500. In other embodiments, two or more of the first clamping portion 300, body portion 102, and/or second clamping portion 700 may be formed of a monolithic body of material.

The first clamping portion 300, body portion 102, and/or second clamping portion 700 may be made of any appropriate material or materials for separating two or more circuit boards from one another. In some embodiments, the first clamping portion 300, body portion 102, and/or second clamping portion 700 may be made of an electrically-insulative material, such as plastic.

The spacer 100 may define a longitudinal (e.g., vertical) axis A. In some embodiments, the body portion 102 may be generally cylindrical about the axis A.

Referring to FIGS. 3 and 4, the first clamping portion 300 may include an upper jaw 302 and an upper flange 304. The upper jaw 302 may be separated from the upper flange 304 by a longitudinal gap 306 in which a circuit board may be received to be retained between the upper jaw 302 and the upper flange 304.

The upper flange may have an upper surface 314 configured to contact a circuit board when the circuit board is disposed in the gap 306. The upper surface 314 may be generally planar, and the plane of the upper surface 314 may be orthogonal to axis A, in some embodiments.

The upper flange 304 may have a first radial diameter DI (labeled in FIG. 4) and a second radial diameter D3 (labeled in FIG. 2). The first radial diameter D1 may be greater than a maximum radial diameter D5 of the body portion 102. The second radial diameter D3 may be less than or equal to the maximum radial diameter D5 of the body portion 102. Similarly, the upper jaw 302 may have a first radial diameter D2 (labeled in FIG. 4) and a second radial diameter D4 (leveled in FIG. 2). The first radial diameter D2 may be greater than the maximum radial diameter D5 of the body portion 102. The second radial diameter D4 may be less than or equal to the maximum radial diameter D5 of the body portion 102. As will be described below, this arrangement of diameters permits the first clamping portion, or a portion thereof, to be extended through an aperture in a circuit board before being clamped to the circuit board.

The first clamping portion 302 may include a lower connection portion 308 configured to be coupled to the body portion 102. The lower connection portion 308 may include, for example, one or more protrusions 310 or apertures configured to be coupled with corresponding apertures or protrusions on the body portion 102. The first clamping portion 300 and the body portion 102 may therefore be configured to be coupled with each other by press-fit, in some embodiments. In other embodiments, the first clamping portion 300 and the body portion 102 may be coupled with each other by friction fit, adhesive, welding, ultrasonic welding, threaded connection, or other appropriate coupling.

The upper jaw 302 may include a chamfered leading lateral edge 312. The chamfered edge 312 may contact a circuit board when the first clamping portion 302 is rotated with the thickness of the circuit board positioned adjacent to the gap 306 and the chamfered edge 312 leading the direction of rotation. In response to that contact, the jaw 302 may flex upward, such that the circuit board is clamped between the jaw 302 and the upper flange 304 as the first clamping portion 302 is rotated.

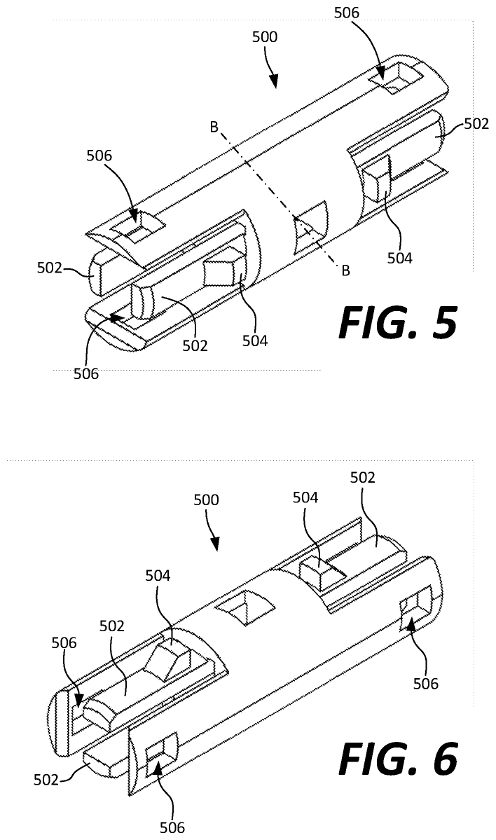

Referring to FIGS. 5 and 6, the body component 500 may be generally cylindrical and may have mirror symmetry across a longitudinal center plane B which is perpendicular to the axis A. Each half of the body component 500 may include two longitudinal arms 502, each with a respective protrusion 504. Each half may also include two lateral apertures 506 configured to receive and couple with the protrusions 504 of another body component 500, or to receive the protrusions of a clamping portion 300 (e.g., protrusions 310).

Due to the symmetrical arrangement of the body component 500 and its configuration to couple with another body component 500, two or more body components 500 may be coupled together to form a body portion 102 of a desired length for a particular circuit board assembly. The spacer 100 may be modular at the time of assembly, with a desired quantity of body components 500 selected and longitudinally joined to each other and to the first clamping portion 300 and/or second clamping portion 700 to create a spacer 100 of a desired height.

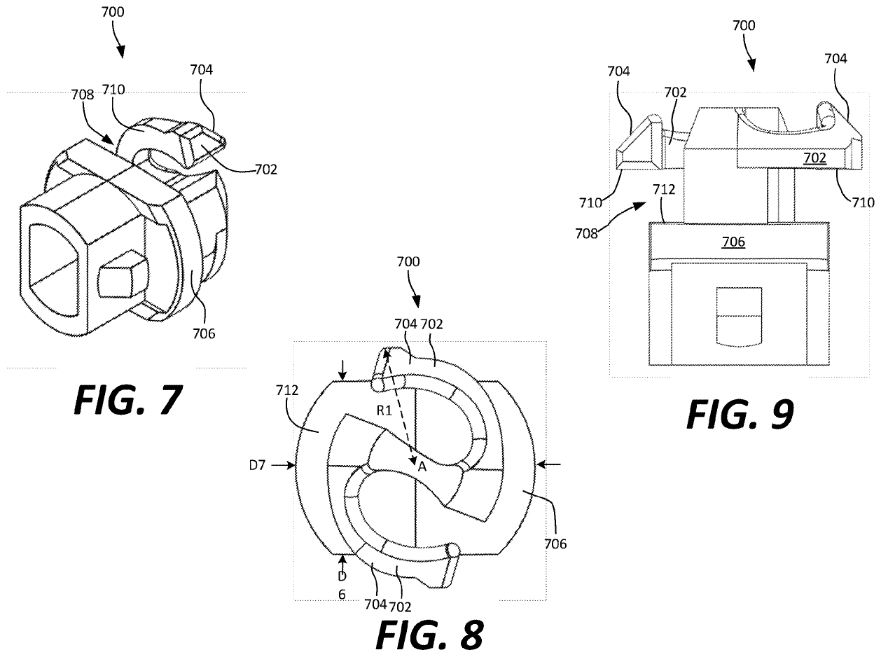

Referring to FIGS. 7, 8, and 9, the second clamping portion 700 may include two lower compressible arms 702 that extend and curve radially outward from a radial center on axis A (labeled in FIG. 8). Each arm 702 may have a maximum radius R1 (labeled in FIG. 8) that is greater than the maximum radius R2 (labelled in FIG. 2) of the body portion 102. Each arm 702 may be radially inwardly flexible to have a compressed radius that is less than or equal to the maximum radius R2 of the body portion 102. In addition, each arm 702 may have a chamfered outer edge 704. As a result, each arm 702 may deflect radially inward in response to longitudinal pressure on the arms (e.g., on the chamfered outer edges 704), such as when the arms 702 are pressed into an aperture of a circuit board. Once through the aperture, the arms may elastically return to their radius R1. The arms 702 may each have a generally planar upper surface 710 that is orthogonal to the axis A, in some embodiments, that may contact a circuit board when the circuit board is clamped in the second clamping portion 700. Accordingly, the upper surface 710 of one arm 702 may be generally co-planar with the upper surface 710 of the other (e.g., each other) arm 702.

Although the second clamping portion 700 is illustrated and described herein with two arms 702, any number of arms may be provided. For example, in some embodiments, a single arm 702 may be provided that extends around most of the circumference of the second clamping portion, or three or more arms may be provided.

The second clamping portion 700 may further include a lower flange 706. The lower flange may be longitudinally separated by a gap 708 from the arms 702. The lower flange 706 may have a first diameter D6 (labeled in FIG. 8) that is less than or equal to the maximum diameter D5 of the body portion 102 and a second diameter D7 (labeled in FIG. 8) that is greater than the maximum diameter D5 of the body portion 102. The first diameter D6 may be radially aligned with (e.g., radially parallel with) the direction of deflection of one or both of the arms 702, in some embodiments. The lower flange 706 may include a generally planar lower surface 712 that is orthogonal to the axis A, in some embodiments, that may contact a circuit board when the circuit board is clamped in the second clamping portion 700. The lower surface 712 may face, and may be generally parallel to, the upper surface 710.

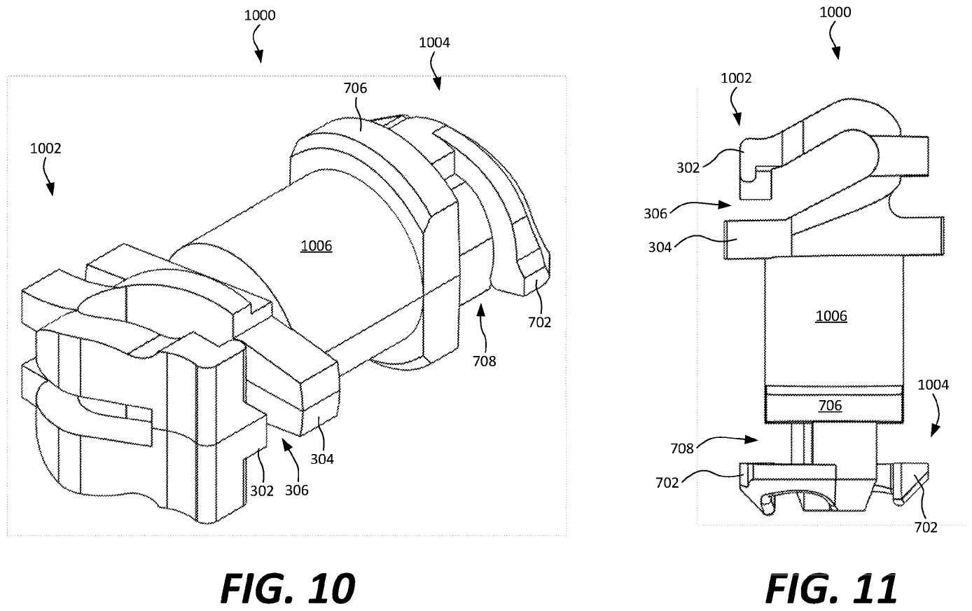

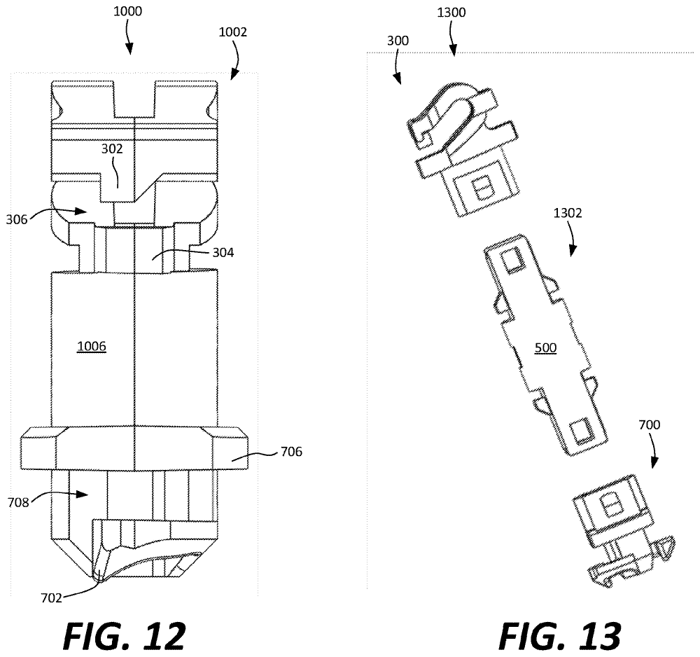

FIGS. 10-12 are various views of a spacer 1000 that is similar in use to the spacer 100, but made of a monolithic body of material. Accordingly, the spacer includes a first clamping portion 1002 having a jaw 302 and flange 304 separated by a gap 306 and a second clamping portion 1004 having two arms 704 and a flange 706 separated by a gap 708. The spacer 1000 also includes a substantially cylindrical body portion 1006 extending longitudinally from the first clamping portion 1002 to the second clamping portion 1004.

FIG. 13 is an exploded perspective view of a spacer 1300 that includes a first clamping portion 300, a second clamping portion 700, and a single body component 500 as a body portion 1302. Comparing the spacer 1300 with the spacer 100, it can be seen that a spacer of a desired height (for a desired spacing between circuit boards) can be assembled by selecting a particular number of body components 500. Spacer 1300 is, once assembled, identical to spacer 1000 in dimensions and clamping features, but is made of modular components.

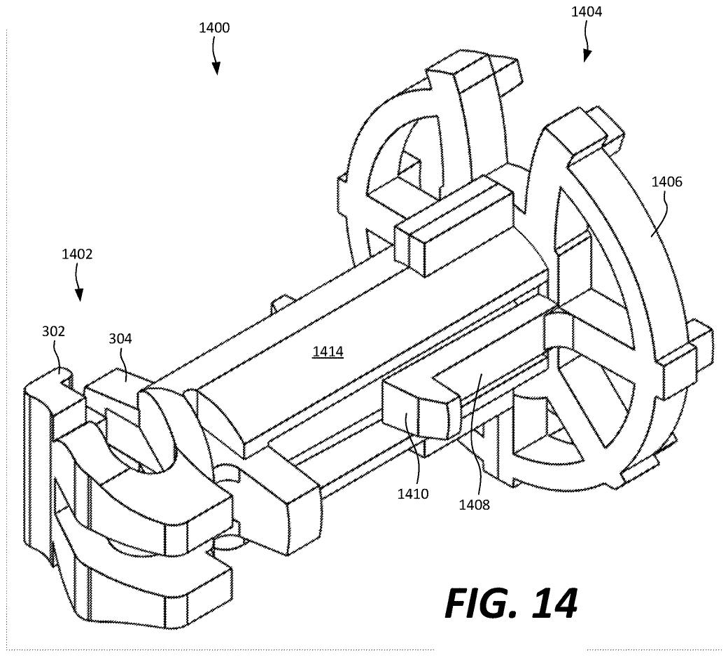

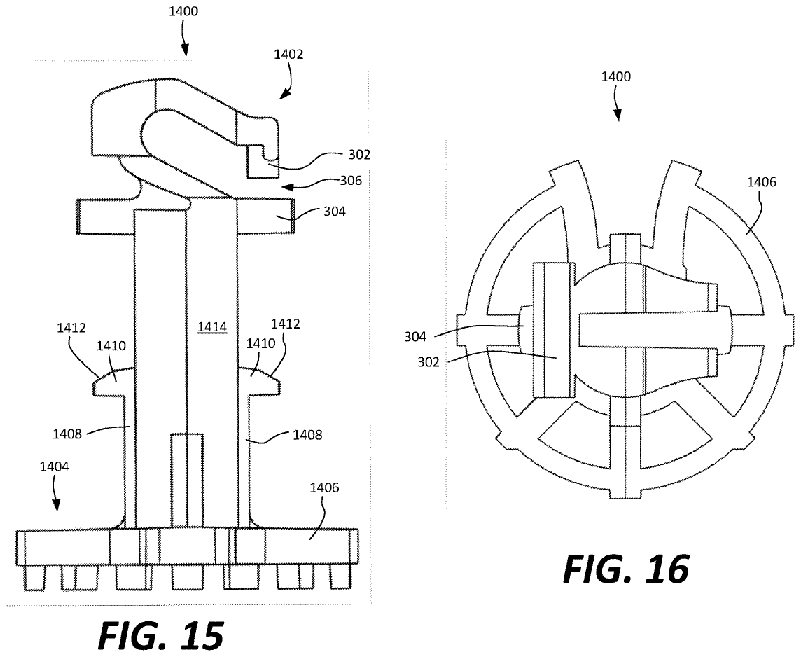

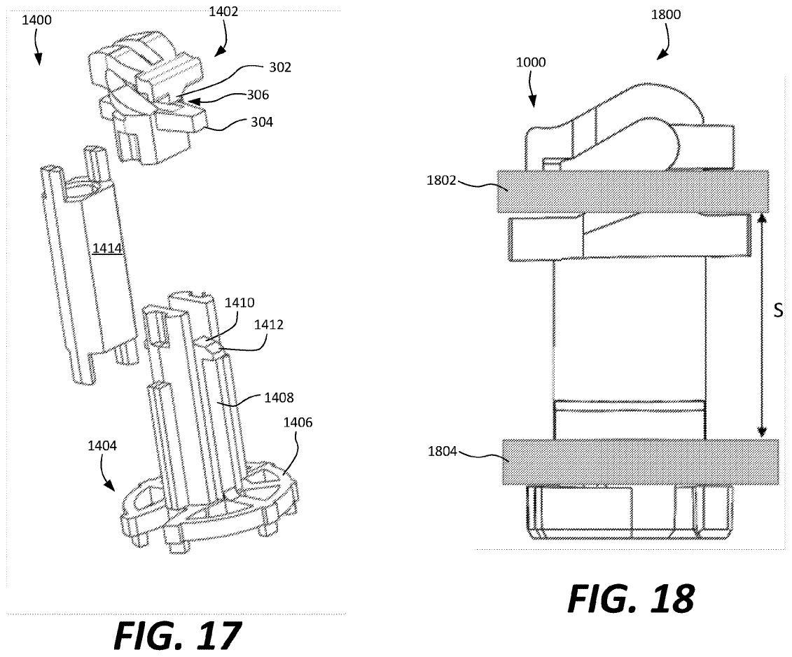

FIGS. 14-17 are various views of a spacer 1400 having a first clamping portion 1402 that is functionally similar to the first clamping portions 300,1002, and thus has a jaw 302 and an upper flange 304 separated by a gap 306. The spacer 1400 may further include a second clamping portion 1404 that includes a lower engagement member 1406 that includes a “wagon wheel”-style structure having an outer rim and radial spokes. The second clamping portion 1404 may further include two longitudinal clips 1408, each having an upper protrusion 1410. Each upper protrusion may have a chamfered outer surface 1412.

The spacer 1400 may further include a body portion 1414 that extends longitudinally from the first clamping portion 1402 to the second clamping portion 1404. In some embodiments, the first clamping portion 1402 and the body portion 1414 may be made from a monolithic body of material, but may be separable from the second clamping portion 1404. In use, the second clamping portion—specifically, the clips 1408 may be inserted through a second circuit board from the bottom, with the lower engagement member 1406 remaining under the second circuit board. The clips may deflect radially inward when the chamfered surfaces 1412 receive longitudinal pressure against the rim of an aperture of the second circuit board and may elastically return when the protrusions 1410 pass through the aperture. The body portion 1414 and upper flange 304 of the first clamping portion 1402 may be inserted through a first circuit board, and the body portion 1414 may be coupled with the clips 1408 in between the circuit boards.

FIG. 18 is a side view of a circuit board assembly 1800 including the spacer 1000 clamping two circuit boards 1802, 1804 in a fixed spatial relationship, with a spacing S between the circuit boards 1802, 1804. Instead of the spacer 1000, one of the spacers 100, 1300, 1400 may be used to clamp the circuit boards 1802, 1804 in a fixed spatial relationship.

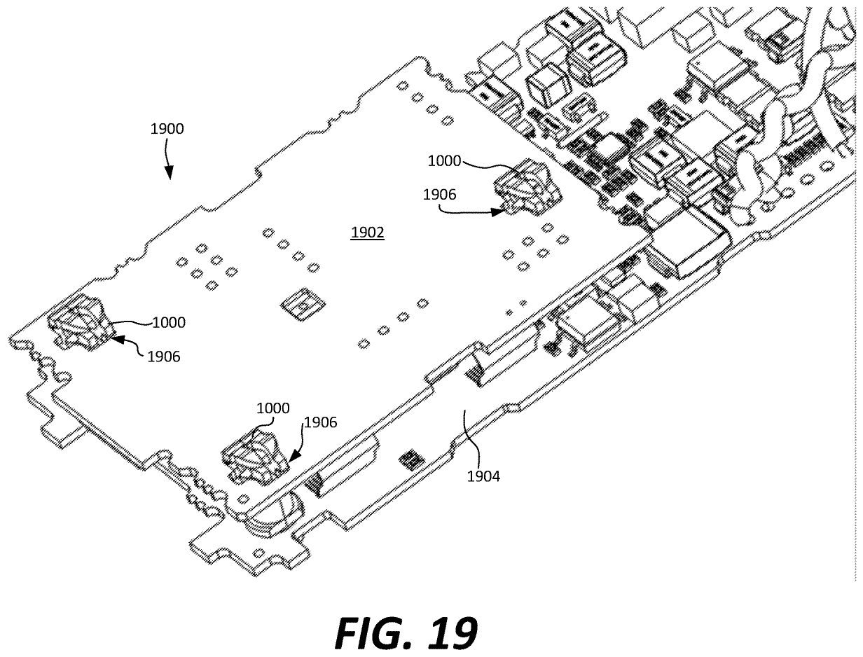

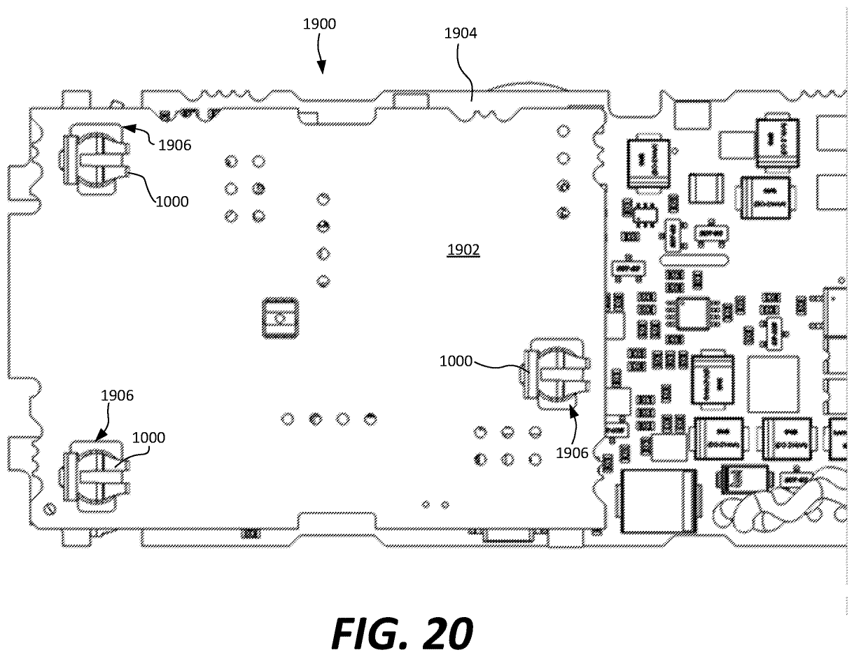

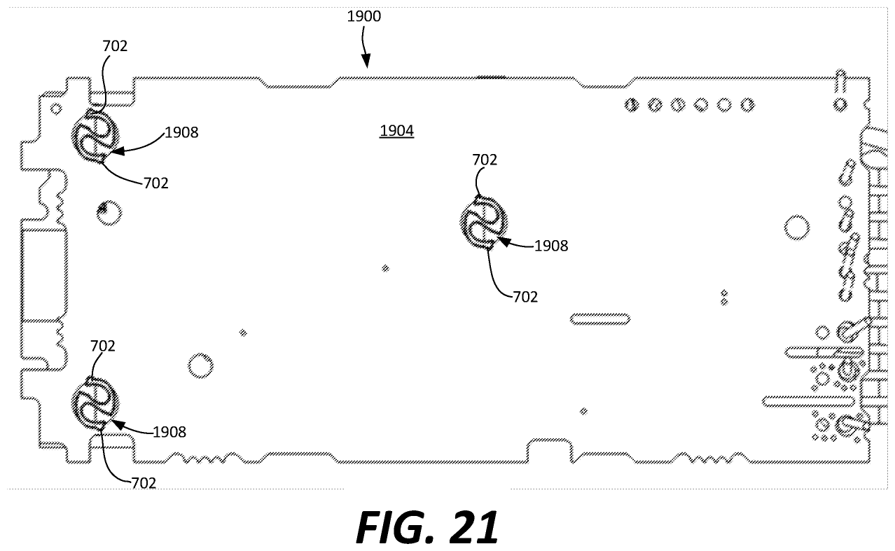

FIGS. 19-21 are various views of a circuit board assembly 1900 in which two circuit boards 1902, 1904 are held in a fixed spatial relationship by three spacers 1000. The assembly 1900 was assembled by inserting the second clamping portions 1004, body portions 1006, and lower flanges 304 through apertures 1906 in the first circuit board 1902 from the top. The arms 702 may also be inserted through apertures 1908 in the second circuit board. The arms 702 may deflect inward while being inserted, and then return to their larger state once passed through the aperture 1908, such that the second circuit board is clamped between the arms 702 and the upper flange 706. When inserted, the spacers 1000 may be in a first rotational state, illustrated in FIG. 19. The spacers 1000 may then be rotated 90 degrees to a second rotational state, illustrated in FIG. 20, such that the jaw 302 and lower flange 304 of the first clamping portion 300 clamp the first circuit board 1902.

Although the spacer 1000 is illustrated in the circuit board assemblies 1800, 1900 of FIGS. 18-21, it should be understood that the spacers 100, 1300, 1400 may equally find use in the assemblies 1800, 1900.

The circuit board assemblies 1800, 1900 may find use in a wide variety of electronic devices. For example, the circuit board assemblies 1800, 1900, and the spacers 100, 1000, 1300, 1400 may find use in DC power electronics and other electronic devices that are tightly encased and intended to be relatively small in size and/or portable, such that stacking multiple circuit boards is desirable. In a particular example, the circuit board assemblies 1700, 1800, and/or the spacers 100, 900, 1200, 1500 may be used in a battery charge level detector or similar sensor device. In a further example, the circuit board assemblies 1700, 1800, and/or the spacers 100, 900, 1200, 1500 may be used in electronics assemblies in which a housing size is sought to be minimized to ease protection against intrusion of water or other fluids (e.g., by reducing the size of seams between housing portions).

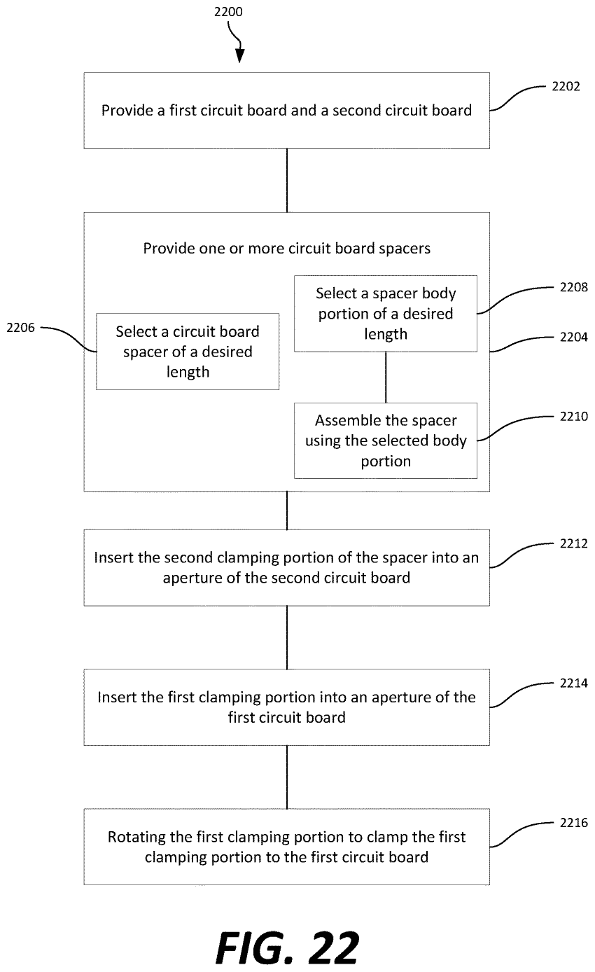

FIG. 22 is a flow chart illustrating an example method 2200 of assembling a circuit board assembly. The method 2200 may include, at block 2202, providing two or more circuit boards to be held in a fixed spatial relationship with respect to one another and, at block 2204, providing one or more circuit board spacers.

Providing each circuit board spacer at block 2204 may include, at sub-block 2206, selecting a circuit board spacer of a desired length from a plurality of circuit board spacer lengths. For example, multiple monolithic spacers (such as spacer 1000) of varying lengths may be available, and a desired length spacer may be selected at sub-block 2206.

As an alternative to sub-block 2206, providing each circuit board spacer at block 2204 may include, at sub-block 2208, selecting a body portion of a desired length for the spacer. For example, a specific-length body portion may be selected from many body portion lengths. In another example, a desired quantity of body portions (e.g., modular body components 500) may be selected and assembled together to create a desired body portion length. Further, at sub-block 2210, the spacer may be assembled using the selected body portion of the desired length. That is, the body portion may be coupled to a first clamping portion and/or a second clamping portion. Coupling different components together may be performed by press fit, friction fit, engagement of threaded components, adhesive, welding, etc.

The method 2200 may further include, at block 2212, for each spacer, inserting a second clamping portion of the spacer into an aperture of the second circuit board. The second clamping portion may clamp on to the second circuit board when inserted, as described herein. In some embodiments, the second clamping portion may be inserted from the bottom of the second circuit board (e.g., using the spacer 1400). In other embodiments, the second clamping portion may be inserted from the top of the second circuit board (e.g., using the spacer 100, 1000, 1300).

The method 2200 may further include, at block 2214, for each spacer, inserting a first clamping portion into an aperture of the first circuit board. In some embodiments, the second clamping portion may also be inserted into and through the aperture of the first circuit board at block 2214 (e.g., when the first and second clamping portions are inserted from the top). In some embodiments, block 2214 may occur before block 2212.

The method 2200 may further include, at block 2216, rotating the first clamping portion to clamp the first clamping portion to the first circuit board.

Assembling a circuit board assembly according to the method 2200, or otherwise using spacers having the features of the present disclosure, may offer several advantages over known spacers and methods of assembly. First, rotating the spacer to clamp a circuit board between a flexible arm of the spacer and a flange or other lower surface, instead of twisting a screw or other threaded component through a hole in the circuit board, imparts less stress on average to the circuit board, thereby protecting traces on the circuit board and components coupled to the board better than known spacers and methods. Second, the use of modular components in certain spacers (e.g., the body components in the spacers 100, 1300) simplifies assembly by permitting a smaller number of spacers and components to be used to assemble a larger number of different circuit board assemblies with different spacing requirements.

In a first aspect of the present disclosure, a circuit board spacer for holding a first circuit board and a second circuit board in a fixed spatial relationship is provided. The spacer includes a first clamping portion configured to clamp to the first circuit board in response to rotation of the first clamping portion with respect to the first circuit board, a second clamping portion configured to clamp to the second circuit board, and a body portion, extending from the first clamping portion to the second clamping portion.

In an embodiment of the first aspect, the body portion has a first diameter, and the first clamping portion comprises a jaw that extends outward of the first diameter. In a further embodiment of the first aspect, the first clamping portion further comprises a second jaw that extends outward of the first diameter, wherein the first clamping portion is configured to clamp the first circuit board between the first jaw and the second jaw.

In an embodiment of the first aspect, the second clamping portion is configured to clamp to the second circuit board in response to the second clamping portion being pressed through an aperture in the second circuit board. In a further embodiment of the first aspect, the second clamping portion comprises a compressible jaw. In a further embodiment of the first aspect, the second clamping portion comprises a flange, wherein the second clamping portion is configured to clamp the second circuit board between the compressible jaw and the flange.

In an embodiment of the first aspect, the body portion has a first diameter, and the second clamping portion comprises a curved arm, wherein the curved arm has an outer diameter that is larger than the first diameter in a first state, wherein the curved arm is configured to compress inward to a second state in which the outer diameter is smaller than the first diameter. In a further embodiment of the first aspect, the curved arm is a first curved arm, and the second clamping portion further includes a second curved arm, wherein the second curved arm has an outer diameter that is larger than the first diameter in a first state, wherein the second curved arm is configured to compress inward to a second state in which the outer diameter of the second arm is smaller than the first diameter. In a further embodiment of the first aspect, the first and second curved arms form an “S” shape.

In an embodiment of the first aspect, the body portion is generally cylindrical.

In a second aspect of the present disclosure, a circuit board assembly is provided. The assembly includes a first circuit board, a second circuit board, and a circuit board spacer for holding the first circuit board and the second circuit board in a fixed spatial relationship. The spacer includes a first clamping portion configured to clamp to the first circuit board in response to rotation of the first clamping portion with respect to the first circuit board, a second clamping portion configured to clamp to the second circuit board, and a body portion, extending from the first clamping portion to the second clamping portion.

In an embodiment of the second aspect, the first circuit board includes a first aperture having a first outer diameter and a second outer diameter, and the first clamping portion includes a jaw having an outer diameter that is larger than the first outer diameter and smaller than the second outer diameter. In a further aspect of the second aspect, the first clamping portion further includes a second jaw, wherein the first clamping portion is configured to clamp the first circuit board between the first jaw and the second jaw.

In an embodiment of the second aspect, the second circuit board includes a second aperture, and the second clamping portion is configured to clamp to the second circuit board in response to the second clamping portion being pressed through the second aperture. In a further embodiment of the second aspect, the second clamping portion includes a compressible jaw. In a further embodiment of the second aspect, the second clamping portion includes a flange, wherein the second clamping portion is configured to clamp the second circuit board between the compressible jaw and the flange. In a further embodiment of the second aspect, the second aperture has a second diameter, and the second clamping portion includes a curved arm, the curved arm has an outer diameter that is larger than the second diameter in a first state, and the curved arm is configured to compress inward to a second state in which the outer diameter is smaller than the second diameter.

In a third aspect of the present disclosure, a method of assembling a circuit board assembly is provided. The method includes providing a first circuit board having a first aperture, a second circuit board having a second aperture, and a circuit board spacer. The circuit board spacer includes a first clamping portion, a second clamping portion, and a body portion, extending from the first clamping portion to the second clamping portion. The method includes inserting the second clamping portion into the second aperture to clamp the second clamping portion to the second circuit board, inserting the first clamping portion into the first aperture, and rotating the first clamping portion with respect to the first circuit board to clamp the first clamping portion to the first circuit board.

In an embodiment of the third aspect, the method further includes selecting the body portion from a plurality of body portion segments, wherein each of the body portion segments has a different length from each other body portion segment, and assembling the selected body portion, the first clamping portion, and the second clamping portion together to form the circuit board spacer.

In an embodiment of the third aspect, the method further includes selecting the circuit board spacer from a plurality of circuit board spacers, wherein each of the circuit board spacers has a different length from each other circuit board spacer.

While various concepts have been described in detail, it will be appreciated by those skilled in the art that various modifications and alternatives to those concepts could be developed in light of the overall teachings of the disclosure. It will be additionally appreciated that the particular concepts disclosed are meant to be illustrative only and not limiting as to the scope of the invention which is to be given the full breadth of the appended claims and any equivalents thereof.

What is claimed is:

1. A circuit board spacer for holding a first circuit board and a second circuit board in a fixed spatial relationship, the spacer comprising:
a first clamping portion configured to clamp to the first circuit board in response to rotation of the first clamping portion with respect to the first circuit board;
a second clamping portion configured to clamp to the second circuit board; and
a body portion, extending from the first clamping portion to the second clamping portion.

2. The circuit board spacer of claim 1, wherein:
the body portion has a first diameter; and
the first clamping portion comprises a jaw that extends outward of the first diameter.

3. The circuit board spacer of claim 2, wherein the first clamping portion further comprises a second jaw that extends outward of the first diameter, wherein the first clamping portion is configured to clamp the first circuit board between the first jaw and the second jaw.

4. The circuit board spacer of claim 1, wherein the second clamping portion is configured to clamp to the second circuit board in response to the second clamping portion being pressed through an aperture in the second circuit board.

5. The circuit board spacer of claim 4, wherein the second clamping portion comprises a compressible jaw.

6. The circuit board spacer of claim 5, wherein the second clamping portion comprises a flange, wherein the second clamping portion is configured to clamp the second circuit board between the compressible jaw and the flange.

7. The circuit board spacer of claim 1, wherein:
the body portion has a first diameter; and
the second clamping portion comprises a curved arm, wherein the curved arm has an outer diameter that is larger than the first diameter in a first state, wherein the curved arm is configured to compress inward to a second state in which the outer diameter is smaller than the first diameter.

8. The circuit board spacer of claim 7 wherein:
the curved arm is a first curved arm; and
the second clamping portion further comprises a second curved arm, wherein the second curved arm has an outer diameter that is larger than the first diameter in a first state, wherein the second curved arm is configured to compress inward to a second state in which the outer diameter of the second arm is smaller than the first diameter.

9. The circuit board spacer of claim 8, wherein the first and second curved arms form an “S” shape.

10. The circuit board spacer of claim 1, wherein the body portion is generally cylindrical.

11. A circuit board assembly comprising:
a first circuit board;
a second circuit board; and
a circuit board spacer for holding the first circuit board and the second circuit board in a fixed spatial relationship, the spacer comprising:
a first clamping portion configured to clamp to the first circuit board in response to rotation of the first clamping portion with respect to the first circuit board;
a second clamping portion configured to clamp to the second circuit board; and
a body portion, extending from the first clamping portion to the second clamping portion.

12. The circuit board assembly of claim 11, wherein:
the first circuit board comprises a first aperture having a first outer diameter and a second outer diameter; and
the first clamping portion comprises a jaw having an outer diameter that is larger than the first outer diameter and smaller than the second outer diameter.

13. The circuit board assembly of claim 12, wherein the first clamping portion further comprises a second jaw, wherein the first clamping portion is configured to clamp the first circuit board between the first jaw and the second jaw.

14. The circuit board assembly of claim 11, wherein:
the second circuit board comprises a second aperture; and
the second clamping portion is configured to clamp to the second circuit board in response to the second clamping portion being pressed through the second aperture.

15. The circuit board assembly of claim 14, wherein the second clamping portion comprises a compressible jaw.

16. The circuit board assembly of claim 15, wherein the second clamping portion comprises a flange, wherein the second clamping portion is configured to clamp the second circuit board between the compressible jaw and the flange.

17. The circuit board assembly of claim 14, wherein:
the second aperture has a second diameter; and
the second clamping portion comprises a curved arm, wherein the curved arm has an outer diameter that is larger than the second diameter in a first state, wherein the curved arm is configured to compress inward to a second state in which the outer diameter is smaller than the second diameter.

18. A method of assembling a circuit board assembly, the method comprising:
providing:
a first circuit board having a first aperture;
a second circuit board having a second aperture; and
a circuit board spacer comprising:
a first clamping portion;
a second clamping portion; and
a body portion, extending from the first clamping portion to the second clamping portion;
inserting the second clamping portion into the second aperture to clamp the second clamping portion to the second circuit board;
inserting the first clamping portion into the first aperture; and
rotating the first clamping portion with respect to the first circuit board to clamp the first clamping portion to the first circuit board.

19. The method of claim 18, further comprising:
selecting the body portion from a plurality of body portion segments, wherein each of the body portion segments has a different length from each other body portion segment; and
assembling the selected body portion, the first clamping portion, and the second clamping portion together to form the circuit board spacer.

20. The method of claim 18, further comprising:
selecting the circuit board spacer from a plurality of circuit board spacers, wherein each of the circuit board spacers has a different length from each other circuit board spacer.
